(19) United States
(12) Patent Application Publication
(10) Pub. No.: US 2004/0109942 A1
(43) Pub. Date: Jun. 10, 2004

(54) Method of producing optical fiber preforms

(75) Inventors: Jacques Jolly, Chatou (FR); Isabelle Decaux, Mantes La Ville (FR); Marie-Pierre Glemot, Andresy (FR); Nathalie Offre, Houilles (FR); Jean-Florent Campion, Conflans St Honorine (FR)

Correspondence Address: SUGHRUE MION, PLLC, Suite 800, 2100 Pennsylvania Avenue, Washington, DC, 20037-3213, US

(73) Assignee: ALCATEL

(21) Appl. No.: 10/720,670

(22) Filed: Nov. 25, 2003

(30) Foreign Application Priority Data
Dec. 5, 2002 (FR) 02 15 332

(51) Int. Cl. B05D 5/06; C23C 16/00

(52) U.S. Cl. 427/163.2; 427/255.28

(57) ABSTRACT

In an FCVD process for producing preforms for dispersion shifted optical fiber or dispersion compensating optical fiber having a core comprising a central portion, an inner cladding, a ring, and an outer cladding by depositing layers, the layers of the preform corresponding to the inner cladding and to the ring of the optical fiber have a phosphorus content not greater than 0.1 wt %.

### CROSS-REFERENCE TO RELATED APPLICATIONS

This application is based on French Patent Application No. 02 15 332 filed Dec. 5, 2002, the disclosure of which is hereby incorporated by reference thereto in its entirety, and the priority of which is hereby claimed under 35 U.S.C. §119.

### BACKGROUND OF THE INVENTION

1. Field of the Invention

The field of the invention is that of methods of producing optical fiber preforms by depositing layers using a chemical vapor deposition (CVD) process. CVD processes include modified chemical vapor deposition (MCVD) processes using a torch, and furnace chemical vapor deposition (FCVD) processes using an inductive or resistive furnace.

2. Description of the Prior Art

One problem of all the above processes is that of increasing their productivity. In CVD processes, the index profile of the optical fiber preform is produced by successively depositing concentric layers of glass on the inside of a glass tube. The thicker the deposited layers, the shorter the cycle time and the higher the productivity.

MCVD processes using a high phosphorus content to reduce the viscosity of the glass to facilitate the vitrification step, allowing the deposition of thick layers and therefore achieving high productivity, are known in the art. When producing optical fiber preforms having a complex dispersion shifted fiber (DSF) type index profile, including in particular non-zero dispersion shifted fiber (NZ-DSF) preforms and dispersion compensating fiber (DCF) preforms, the core of which comprises at least three slices, namely a central portion, an inner cladding, and a ring, to which core an external cladding is added, the content of phosphorus in the layers of the preform corresponding to the inner cladding and to the ring is from 0.2 wt % to 0.4 wt %. The central portion of the core, which has a relatively high index, contains no phosphorus and is produced from thinner layers.

An FCVD process achieving good productivity by depositing thick layers is also known in the art, for example from patent application FR 2742743, a furnace heating better than a torch, but there is no indication as to any use of phosphorus to improve vitrification and no mention of the particular problem of optical fiber preforms with a complex index profile.

In the case of optical fiber preforms with a complex index profile, phosphorus has the disadvantage of producing imprecise index profiles, which results in optogeometrical parameters that are not well controlled, especially if the index profile is complex, this problem affecting most of all the dispersion slope, which is a great problem in the case of dispersion shifted fibers and dispersion compensating fibers. An imprecise index profile has in particular “waves” between each deposit layer and the next. The first prior art discussed above has the drawback of using too high a phosphorus content, yielding optical fiber preforms with imprecise index profiles. The second prior art discussed above does not address the particular problem of optical fiber preforms with complex index profiles and does not indicate the phosphorus content.

To increase productivity whilst producing precise index profiles, in the context of producing optical fiber preforms with complex index profiles of the DSF or DCF type comprising at least one inner cladding and one ring, the invention proposes to combine the use of a furnace as heating means, i.e. an FCVD process, and a content of phosphorus, used as a fusing agent facilitating vitrification, of less than or equal to 0.1 wt %, at least in the layers of the preform corresponding to the inner cladding and the ring of the optical fiber. It is the use of an FCVD process, a furnace being much more efficient than a torch at heating a preform, that enables the phosphorus content to be reduced whilst preserving correct vitrification in order to preserve correct productivity. With a torch, it would be necessary to maintain a high phosphorus content to preserve correct vitrification during deposition of thick layers; with a torch, in the absence of phosphorus, only thin layers can be deposited, which is detrimental to productivity.

### SUMMARY OF THE INVENTION

According to the invention, there is provided a CVD process for producing preforms for dispersion shifted optical fiber or dispersion compensating optical fiber having a core comprising a central portion, an inner cladding, a ring, and an outer cladding, by depositing layers, in which method the layers of the preform corresponding to the inner cladding and to the ring of the optical fiber have a phosphorus content not greater than 0.1 wt %.

In a preferred embodiment, a low but non-zero phosphorus content is chosen, in order to preserve good vitrification, yielding improved productivity. In fact, even a very small quantity of phosphorus can significantly improve vitrification and thereby significant increase productivity, and if the quantity of phosphorus is sufficiently low, it will have no negative effect, or only a negligible effect, on the sharpness of the index profiles. On the other hand, a total absence of phosphorus can lead to vitrification problems in certain cases. A good compromise between a sharp index profile and good vitrification leading to high productivity is preferably achieved when the layers of the preform corresponding to the inner cladding and to the ring of the optical fiber have a phosphorus content from 0.03 wt % to 0.1 wt %.

The layers of the preform corresponding to the outer cladding of the optical fiber advantageously have a phosphorus content in the same range of values as the layers of the preform corresponding to the inner cladding and to the ring of the optical fiber, i.e. from 0% to 0.1% and preferably from 0.03% to 0.1%.

The layers are advantageously deposited at a pressure within 20% of atmospheric pressure, and not at low pressure or very low pressure, for example one tenth or one hundredth of an atmosphere, a higher dopant partial pressure increasing the quantity of material available and thus the size of the soot particles deposited.

The method according to the invention, which eliminates or greatly reduces the content of phosphorus in the final optical fiber, is particularly advantageous if the optical fiber is intended to be integrated into a submarine cable, because a high phosphorus content increases the sensitivity of the optical fiber to the gamma rays emitted by deep sea, and gamma rays gradually increase the attenuation of the optical fiber.

There is claimed:

1. A CVD process for producing preforms for dispersion shifted optical fiber or dispersion compensating optical fiber having a core comprising a central portion, an inner cladding, a ring, and an outer cladding, by depositing layers, in which process the layers of said preform corresponding to said inner cladding and to said ring of said optical fiber have a phosphorus content not greater than 0.1 wt %.

2. The optical fiber preform production process claimed in 1 wherein said layers of said preform corresponding to said inner cladding and to said ring of said optical fiber have a phosphorus content from 0.03 wt % to 0.1 wt %.

3. The optical fiber preform production process claimed in claim 1 wherein said layers of said preform corresponding to said outer cladding of said optical fiber have a phosphorus content in the same range of values as said layers of said preform corresponding to said inner cladding and to said ring of said optical fiber.

4. The optical fiber preform production process claimed in claim 1 wherein said layers are deposited at a pressure within 20% of atmospheric pressure.

5. The optical fiber preform production process claimed in claim 1, when said optical fiber is intended to be integrated into a submarine cable.
